(19) United States
(12) Patent Application Publication
(10) Pub. No.: US 2004/0130397 A1
(43) Pub. Date: Jul. 8, 2004

(54) Transimpedance amplifier for photodiode

(76) Inventor: Iain Ross Mactaggart, Eden Prairie, MN (US)

Correspondence Address: SCHWEGMAN, LUNDBERG, WOESSNER & KLUTH, P.A., P.O. BOX 2938, MINNEAPOLIS, MN, 55402, US

(21) Appl. No.: 10/337,207

(22) Filed: Jan. 6, 2003

(51) Int. Cl. H03F 3/08

(52) U.S. Cl. 330/308

(57) ABSTRACT

This document describes systems and methods for providing an interface apparatus for a photodiode, including a fully differential transimpedance amplifier. A first transimpedance amplifier input is coupled to a regulated bias voltage through the photodiode. A second transimpedance amplifier input is coupled to the regulated bias voltage through an on-chip programmably adjustable capacitor. The programmably adjustable capacitor is adjusted such that its capacitance value substantially matches that of the reverse-biased photodiode. This reduces or eliminates mismatch in coupling of noise from the regulated bias voltage onto the first and second inputs of the transimpedance amplifier.

### TECHNICAL FIELD

This document relates generally to optical and electronic data communication systems and methods, and particularly, but not by way of limitation, to systems and methods for providing a transimpedance amplifier for a photodiode.

### BACKGROUND

High-speed data communication often uses optical signals (light) communicated using optical fibers. Such optical fibers typically must interface with optoelectronic components, such as a transmitter that outputs an optical signal in response to an input electrical signal, or a receiver that detects a received optical signal and outputs a resulting electrical signal. The electronics of such optoelectronic components (e.g., a laser and accompanying circuitry of a transmitter, or a semiconductor diode light detector (“photodiode”), or other light detector, and accompanying circuitry of a receiver, or both) may be carried by or housed in an optical subassembly (OSA) module.

The receiver detects light received by a photodiode from an optical fiber. The photodiode is reverse-biased, such that the light received by the photodiode produces a resulting photocurrent. A transimpedance amplifier converts the photocurrent into a responsive voltage signal. The transimpedance amplifier may also provide voltage amplification of the responsive voltage signal. The present inventors have recognized an unmet need for providing a transimpedance amplifier photodiode interface that provides, among other things, improved power supply rejection, improved substrate noise rejection, and/or improved stability characteristics.

### BRIEF DESCRIPTION OF THE DRAWINGS

In the drawings, which are offered by way of example, and not by way of limitation, and which are not necessarily drawn to scale, like numerals describe substantially similar components throughout the several views. Like numerals having different letter suffixes represent different instances of substantially similar components.

FIG. 1 is a schematic diagram illustrating generally, by way of example, but not by way of limitation, one embodiment of an interface apparatus for interfacing to a photodiode.

FIG. 2 is a flow chart illustrating generally, by way of example, but not by way of limitation, one technique of operating a photodiode interface apparatus.

### DETAILED DESCRIPTION

In the following detailed description, reference is made to the accompanying drawings, which form a part hereof, and in which is shown by way of illustration specific embodiments in which the invention may be practiced. These embodiments are described in sufficient detail to enable those skilled in the art to practice the invention, and it is to be understood that the embodiments may be combined, or that other embodiments may be utilized and that structural, logical and electrical changes may be made without departing from the scope of the present invention. The following detailed description is, therefore, not to be taken in a limiting sense, and the scope of the present invention is defined by the appended claims and their equivalents.

In this document, the terms “a” or “an” are used, as is common in patent documents, to include one or more than one. Furthermore, all publications, patents, and patent documents referred to in this document are incorporated by reference herein in their entirety, as though individually incorporated by reference. In the event of inconsistent usages between this documents and those documents so incorporated by reference, the usage in the incorporated reference(s) should be considered supplementary to that of this document; for irreconcilable inconsistencies, the usage in this document controls.

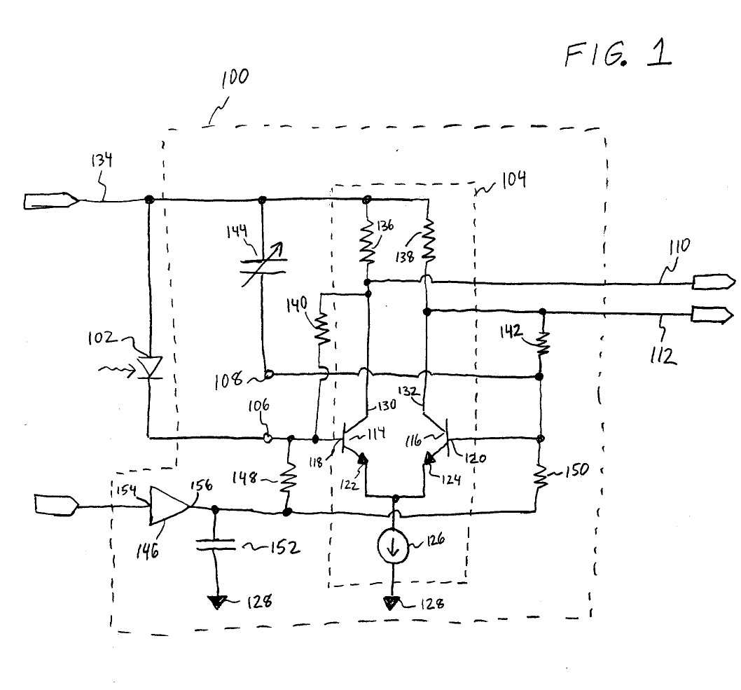

FIG. 1 is a schematic diagram illustrating generally, by way of example, but not by way of limitation, one embodiment of an interface apparatus 100 for interfacing to a photodiode 102. Reverse-biased photodiode 102 receives light (e.g., from an optical fiber) and produces a resulting photocurrent in response thereto. Interface apparatus 100 includes a transimpedance amplifier 104 that converts the photocurrent into a responsive voltage.

In this example, transimpedance amplifier 104 includes transimpedance amplifier inputs 106 and 108 and transimpedance amplifier outputs 110 and 112. Input transistors 114 and 116 include corresponding control (e.g., base terminal) inputs 118 and 120 that are connected to respective transimpedance amplifier inputs 106 and 108. In this example, input transistors 114 and 116 are illustrated as NPN bipolar junction transistors (BJTs), with corresponding emitters 122 and 124 connected to each other and to a common terminal of current source 126. The other terminal of current source 126 is connected to ground node 128. Input transistors 114 and 116 include corresponding collectors 130 and 132 that are respectively coupled to a regulated bias voltage node 134 through corresponding load resistors 136 and 138. Interface apparatus 100 also includes feedback resistors 140 and 142 around transimpedance amplifier 104. More particularly, feedback resistor 140 is coupled between amplifier input 106 and amplifier output 110. Feedback resistor 142 is coupled between transimpedance amplifier input 120 and transimpedance amplifier output 112.

In this example, interface apparatus 104 also includes a programmably adjustable capacitor 144 coupled between transimpedance amplifier input 108 and regulated bias voltage node 134. In one example, programmably adjustable capacitor 144 is located on the same integrated circuit as transimpedance amplifier 104. In one example, programmably adjustable capacitor 144 is implemented as an array of capacitor elements with corresponding switches for switching in a desired number of capacitor elements to obtain a desired capacitance value that substantially matches the capacitance of photodiode 102. Such a fully differential configuration of transimpedance amplifier 104, as illustrated in FIG. 1, and a capacitor 144 having a capacitance value that is programmably adjusted to match the capacitance value of photodiode 102, reduces any mismatch in power supply or other noise coupled from regulated bias voltage node 134 onto the inputs of transimpedance amplifier 104. With any such mismatch reduced or eliminated, any power supply or other noise coupled from regulated bias voltage node 134 onto the inputs of transimpedance amplifier 104 will be attenuated by the common-mode rejection ratio provided by the fully differential amplifier configuration of transimpedance amplifier 104. In one example (but not by way of limitation) the capacitance value of photodiode 102 is about 0.6 picofarads (pF), and is substantially attributable to the depletion capacitance of the reverse-biasing of photodiode 102. Capacitor 144 is programmably adjusted to substantially match this value.

This example also includes an active common-mode biasing circuit for providing a dc bias voltage to transimpedance amplifier inputs 106 and 108. In this example, the common-mode biasing circuit includes an active driver circuit 146, biasing resistors 148 and 150, and capacitor 152. In this example, driver circuit 146 includes an input terminal 154, which is coupled to receive an input common-mode biasing voltage, and an output terminal 156, which is coupled to provide an output common-mode dc biasing voltage to transimpedance amplifier inputs 106 and 108 through biasing resistors 148 and 150, respectively. Capacitor 152 is coupled between output terminal 156 of driver circuit 146 and ground node 128 (or another suitable ground or AC virtual ground node). The RC network formed by biasing resistors 148 and 150 and capacitor 152 stabilizes the actively driven voltage at the output terminal 156 of driver circuit 146.

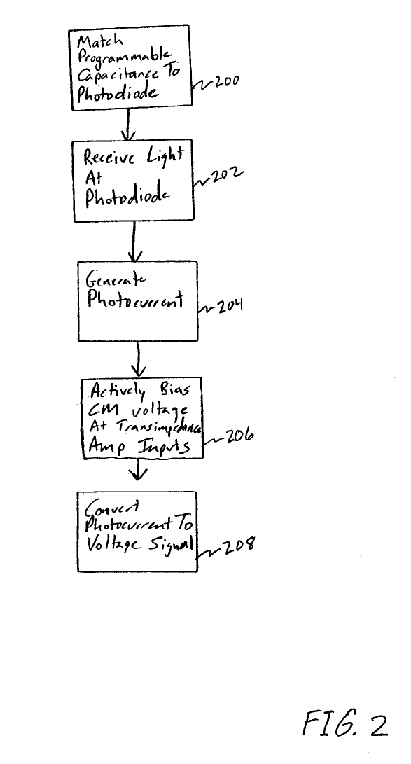

FIG. 2 is a flow chart illustrating generally, by way of example, but not by way of limitation, one technique of operating interface apparatus 100. In this example, at 200, a capacitance value of on-chip capacitor 144 is programmed to match the capacitance of reverse-biased photodiode 102. At 202, light is received at photodiode 102. At 204, photodiode 102 generates a photocurrent in response to the received light. At 206, the active common-mode biasing circuit is used to actively bias the common-mode dc input voltage at the inputs of transimpedance amplifier 104. At 208, the photocurrent is converted to a responsive voltage signal using transimpedance amplifier 104.

It is to be understood that the above description is intended to be illustrative, and not restrictive. For example, the above-discussed embodiments may be used in combination with each other. In another example, the input transistors 114 and 116 are implemented as field-effect transistors (FETs), instead of BJTs, and are connected in a common-source differential pair configuration. In a further example, transimpedance amplifier 104 may include one or more additional voltage gain stages, such as cascaded to its outputs 110 and 112; such gain stages may be conceptualized as being part of, or separate from, transimpedance amplifier 104. Many other embodiments will be apparent to those of skill in the art upon reviewing the above description. The scope of the invention should, therefore, be determined with reference to the appended claims, along with the full scope of equivalents to which such claims are entitled. In the appended claims, the terms “including” and “in which” are used as the plain-English equivalents of the respective terms “comprising” and “wherein.” Moreover, the terms “first,” “second,” “third,” etc. are used merely as labels, and are not intended to impose numeric requirements on their objects.

What is claimed is:

1. An apparatus comprising:
a regulated bias voltage node;
a transimpedance amplifier, including first and second transimpedance amplifier inputs, and including first and second transimpedance amplifier outputs;
a programmably adjustable capacitor, located on the same integrated circuit as the transimpedance amplifier, the adjustable capacitor including a first capacitor terminal coupled to the regulated bias voltage node, the adjustable capacitor including a second capacitor terminal coupled to the second transimpedance amplifier input; and
a photodiode, the photodiode including a first photodiode terminal coupled to the regulated bias voltage node, the photodiode including a second photodiode terminal coupled to the first transimpedance amplifier output.

2. The apparatus of claim 1, in which the transimpedance amplifier includes:
a first input transistor, including a first control terminal coupled to the first transimpedance amplifier input, a first emitter/source terminal, and a first collector/drain terminal coupled to the first transimpedance amplifier output;
a second input transistor, including a second control terminal coupled to the second transimpedance amplifier input, a second emitter/source terminal coupled to the first emitter/source terminal of the first input transistor, and a second collector/drain terminal coupled to the second transimpedance amplifier output;
a first load resistor, coupled between the first transimpedance amplifier output and the regulated bias voltage node;
a second load resistor, coupled between the second transimpedance amplifier output and the regulated bias voltage node.

3. The apparatus of claim 2, further comprising:
a first feedback resistor, coupled between the first transimpedance amplifier output and the first transimpedance amplifier input; and
a second feedback resistor, coupled between the second transimpedance amplifier output and the second transimpedance amplifier input.

4. The apparatus of claim 3, further comprising a common-mode bias voltage circuit coupled to each of the first and second transimpedance amplifier inputs, the common-mode bias voltage circuit including:
a common mode bias voltage input node;
a driver circuit, including a driver input and a driver output, the driver input coupled to the common mode bias voltage input node;
a first bias resistor coupled between the driver output and the first transimpedance amplifier input; and
a second bias resistor coupled between the driver output and the second transimpedance amplifier input.

5. The apparatus of claim 4, in which the common-mode bias voltage circuit further comprises:
a ground node; and
a capacitor coupled between the ground node and the driver output.

6. The apparatus of claim 5, in which the transimpedance amplifier further includes a current source, the current source including a first current source terminal coupled to each of the emitter/source terminals of the respective first and second input transistors, the current source further including a second current source terminal coupled to the ground node.

7. An apparatus comprising:
a regulated bias voltage node;
a transimpedance amplifier, including first and second transimpedance amplifier inputs, and including first and second transimpedance amplifier outputs, the first transimpedance amplifier input providing an input impedance configured for receiving a photodiode coupled between the first transimpedance amplifier input and the regulated bias voltage node, and wherein the first transimpedance amplifier includes:
a first input transistor, including a first control terminal coupled to the first transimpedance amplifier input, a first emitter/source terminal, and a first collector/drain terminal coupled to the first transimpedance amplifier output;
a second input transistor, including a second control terminal coupled to the second transimpedance amplifier input, a second emitter/source terminal coupled to the first emitter/source terminal of the first input transistor, and a second collector/drain terminal coupled to the second transimpedance amplifier output;
a first load resistor, coupled between the first transimpedance amplifier output and the regulated bias voltage node; and
a second load resistor, coupled between the second transimpedance amplifier output and the regulated bias voltage node; and
a programmably adjustable capacitor, located on the same integrated circuit as the transimpedance amplifier, the adjustable capacitor including a first capacitor terminal coupled to the regulated bias voltage node, the adjustable capacitor including a second capacitor terminal coupled to the second transimpedance amplifier input;

8. The apparatus of claim 7, further comprising:
a first feedback resistor, coupled between the first transimpedance amplifier output and the first transimpedance amplifier input; and
a second feedback resistor, coupled between the second transimpedance amplifier output and the second transimpedance amplifier input.

9. The apparatus of claim 8, further comprising a common-mode bias voltage circuit coupled to each of the first and second transimpedance amplifier inputs, the common-mode bias voltage circuit including:
a common mode bias voltage input node;
a driver circuit, including a driver input and a driver output, the driver input coupled to the common mode bias voltage input node;
a first bias resistor coupled between the driver output and the first transimpedance amplifier input; and
a second bias resistor coupled between the driver output and the second transimpedance amplifier input.

10. The apparatus of claim 9, in which the common-mode bias voltage circuit further comprises:
a ground node; and
a capacitor coupled between the ground node and the driver output.

11. The apparatus of claim 10, in which the transimpedance amplifier further includes a current source, the current source including a first current source terminal coupled to each of the emitter/source terminals of the respective first and second input transistors, the current source further including a second current source terminal coupled to the ground node.

12. The apparatus of claim 7, further including a photodiode, the photodiode including a first photodiode terminal coupled to the regulated bias voltage node, the photodiode including a second photodiode terminal coupled to the first transimpedance amplifier output.

13. A method comprising:
programming a capacitance value of an adjustable capacitor, located on an integrated circuit with a transimpedance amplifier, to match a capacitance of the photodiode;
receiving light at a photodiode;
generating a photocurrent using the received light; and
converting the photocurrent into a responsive voltage signal using the transimpedance amplifier.

14. The method of claim 13, further comprising actively biasing a common-mode voltage at first and second inputs of the transimpedance amplifier.

15. The method of claim 13, in which the act of programming the capacitance value is carried out before the act of receiving light at the photodiode.
